(19) United States
(12) Patent Application Publication
(10) Pub. No.: US 2015/0070039 A1
(43) Pub. Date: Mar. 12, 2015

(54) APPARATUS OF MEASURING SEMICONDUCTOR DEVICE

(71) Applicant: Kabushiki Kaisha Toshiba, Tokyo (JP)

(72) Inventor: Masahiro Shimura, Ishikawa-ken (JP)

(73) Assignee: Kabushiki Kaisha Toshiba, Tokyo (JP)

(21) Appl. No.: 14/195,017

(22) Filed: Mar. 3, 2014

(30) Foreign Application Priority Data
Sep. 12, 2013 (JP) 2013-188983

(51) Int. Cl. G01R 31/26; G01R 1/04; G01R 1/067

(52) U.S. Cl. CPC G01R 31/2621; G01R 1/067; G01R 1/0416
USPC 324/754.11

(57) ABSTRACT

According to one embodiment, an apparatus of measuring a semiconductor device includes a first sense terminal, a first force terminal, a second sense terminal, and a plurality of second force terminals. The first sense terminal is configured to be electrically connected to a first electrode provided on a first surface of a semiconductor device. The first force terminal is configured to be electrically connected to the first electrode of the semiconductor device. The second sense terminal is configured to be electrically connected to a second electrode provided on a second surface of the semiconductor device. The second surface is opposite to the first surface. The plurality of second force terminals is disposed in a circumference of the second sense terminal, and is configured to be electrically connected to the second electrode of the semiconductor device.

### CROSS REFERENCE TO RELATED APPLICATION

This application is based upon and claims the benefit of priority from the prior Japanese Patent Application No. 2013-188983, filed on Sep. 12, 2013, the entire contents of which are incorporated herein by reference.

### FIELD

Embodiments described herein relate generally to an apparatus of measuring a semiconductor device.

### BACKGROUND

In order to satisfy a requirement for weight-saving and space-saving in electronic devices, a demand to a semiconductor product shifts to a first semiconductor product from a second semiconductor product. The first semiconductor product has a bare semiconductor chip which is formed by dicing a wafer. The second semiconductor product has a package in which a semiconductor chip is covered with a resin.

A test of the first semiconductor product is performed per wafer before dicing the wafer, and also performed per chip after dicing the wafer.

However, the test of the first semiconductor product has a lot of restrictions compared with a test of the second semiconductor product. Especially, it is difficult to precisely measure ON voltage and ON resistance of a power MOSFET or the like.

### BRIEF DESCRIPTION OF THE DRAWINGS

FIG. 1 is an example of a schematic perspective view showing a wafer W as a measuring object in an apparatus of measuring a semiconductor device according to a first embodiment;

FIG. 2 is an example of a schematic sectional view showing the wafer W according to the first embodiment;

FIG. 3 is an example of a plan view showing a semiconductor chip C according to the first embodiment;

FIG. 4 is an example of a back view showing the semiconductor chip C according to the first embodiment;

FIG. 5 is an example of a sectional view showing the semiconductor chip C according to the first embodiment;

FIG. 6 is a schematic diagram explaining a configuration of the apparatus of measuring the semiconductor device according to the first embodiment;

FIG. 7 is a schematic view explaining an apparatus of measuring a semiconductor device of a comparative example according to the first embodiment;

FIG. 8 is a schematic view explaining an advantage according to the first embodiment;

FIGS. 9 and 10 are schematic diagrams explaining a configuration of an apparatus of measuring a semiconductor device according to a second embodiment;

FIG. 11 is a schematic diagram explaining a configuration of an apparatus of measuring a semiconductor device according to a third embodiment;

FIG. 12 is a schematic diagram explaining a configuration of an apparatus of measuring a semiconductor device according to a fourth embodiment;

### DETAILED DESCRIPTION

According to one embodiment, an apparatus of measuring a semiconductor device includes a first sense terminal, a first force terminal, a second sense terminal, and a plurality of second force terminals. The first sense terminal is configured to be electrically connected to a first electrode provided on a first surface of a semiconductor device. The first force terminal is configured to be electrically connected to the first electrode of the semiconductor device. The second sense terminal is configured to be electrically connected to a second electrode provided on a second surface of the semiconductor device. The second surface is opposite to the first surface. The plurality of second force terminals is disposed in a circumference of the second sense terminal, and is configured to be electrically connected to the second electrode of the semiconductor device.

Hereinafter, embodiments will be described with reference to the drawings. In the drawings, same reference characters denote the same or similar portions. The same numbers are given to the same portions in the drawings, and the detailed description of the same portions will be arbitrarily omitted, and the different portions will be described.

### First Embodiment

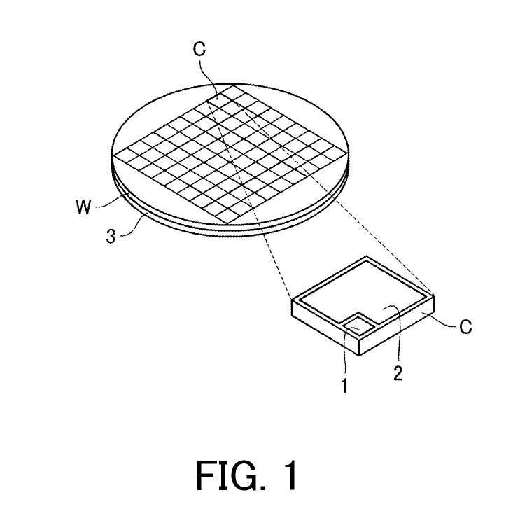

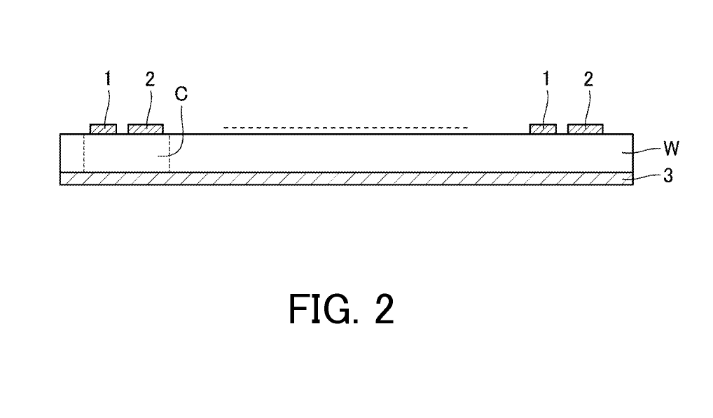

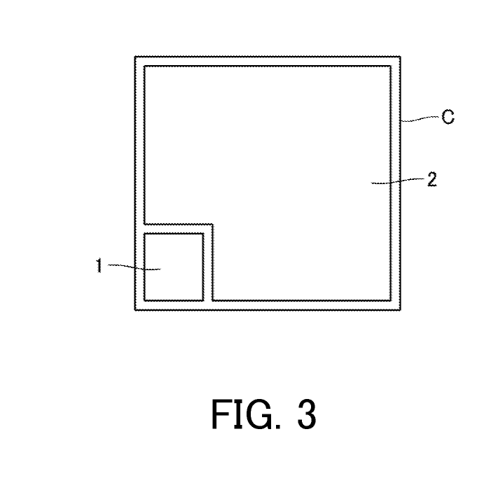

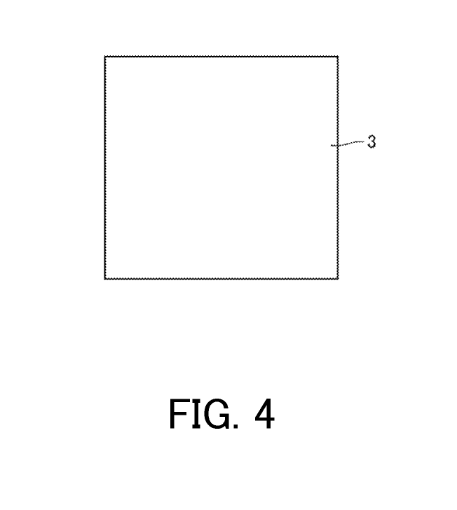

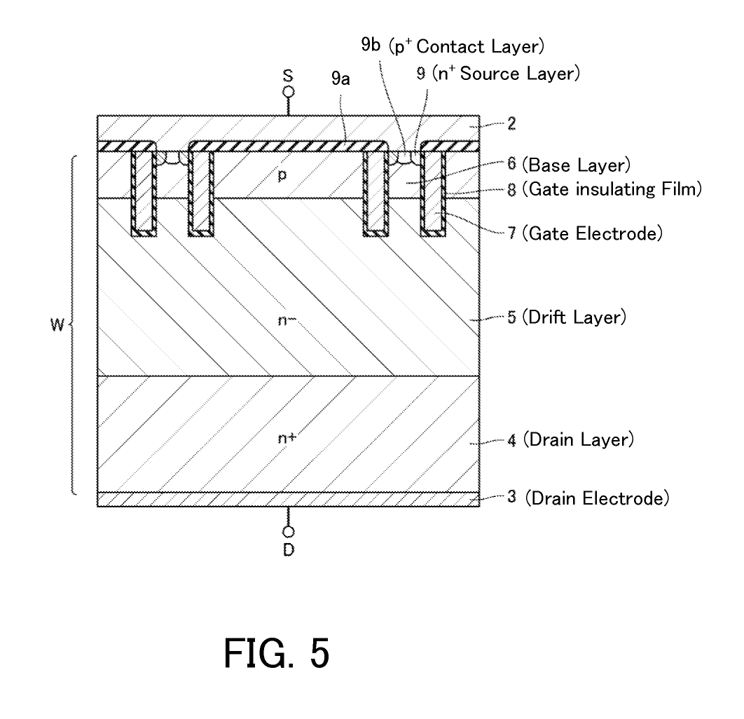

An apparatus of measuring a semiconductor device in accordance with a first embodiment will be described with reference to FIG. 1. Structures of a semiconductor chip C and a wafer W which are measuring objects in the apparatus of measuring the semiconductor device of the embodiment will be described with reference to FIGS. 1 and 5 before description of the apparatus of measuring the semiconductor device. FIG. 1 is an example of a schematic perspective view of the wafer W. FIG. 2 is an example of a schematic sectional view of the wafer W. FIG. 3 is an example of a plan view of the semiconductor chip C. FIG. 4 is an example of a back view of the semiconductor chip C. FIG. 5 is an example of a sectional view of the semiconductor chip C. The semiconductor chip C will be described as a power MOSFET chip, for example. However, the semiconductor chip C is not limited to the power MOSFET chip.

As shown in FIG. 1, the several hundred to several thousand semiconductor chips C are provided in the wafer W. Each of the semiconductor chips C is recognized as the measuring object in the apparatus of measuring the semiconductor device of the embodiment after dicing. The wafer W is also recognized as the measuring object before dicing. As shown in FIGS. 1, 2 and 4, a drain electrode 3 (a first electrode) is provided on a whole rear surface of the wafer W. As shown in FIGS. 1, 2 and 3, in an upper surface of the wafer W, a gate electrode 1 and a source electrode 2 (a second electrode) are provided on every semiconductor chip C.

FIG. 5 is a sectional view of the semiconductor chip C (the power MOSFET chip). The semiconductor chip C includes the drain electrode 3, an n⁺-type drain layer 4, an n⁻-type drift layer 5, a p-type base layer 6 and the source electrode 2, which are arranged in order from the rear surface to the upper surface of the wafer W. The drain layer 4 is an n⁺-type semiconductor region which functions as a drain region of the power MOSFET. The drain layer 4 is provided on the whole rear surface of the wafer W. The drift layer 5 is formed on the drain layer 4, and is an n⁻-type semiconductor region which functions as a drift region of the power MOSFET. The drift layer 5 has an impurity concentration lower than an impurity concentration of the drain layer 4.

The base layer 6 is provided on the drift layer 5, and is a p-type semiconductor region which functions as a channel region of the power MOSFET. Passing through the base layer 6, a gate electrode 7 extends so as to reach the drift layer 5. A gate insulating film 8 such as a silicon oxide film, for example is provided between the gate electrode 7 and the base layer 6. An n⁺-type source layer 9 is provided inside the base layer 6 from an upper surface of the base layer 6, the source layer 9 is in contact with the gate insulating film 8. The source layer 9 is a semiconductor region which functions as a source region of the power MOSFET. When a voltage equal to or above a threshold voltage is applied to the gate electrode 7, an inversion layer is formed in the base layer 6 to flow current from the source to the drain (the MOSFET is in conduction state).

The source electrode 2 is provided on the upper surface of the semiconductor chip C with an interlayer dielectric film 9a interposed therebetween. The source electrode 2 is electrically connected to the source layer 9 and p+-type contact layer 9b which are provided inside the base layer 6 from the upper surface of the base layer 6. In addition, the power MOSFET shown in FIG. 5 is just an example of the semiconductor device. The apparatus of measuring the semiconductor device of the embodiment may be commonly adaptable to a vertical-type semiconductor device which has a rear electrode (a first electrode) on the rear surface of the wafer W and an upper electrode (a second electrode) on the upper surface of the wafer W.

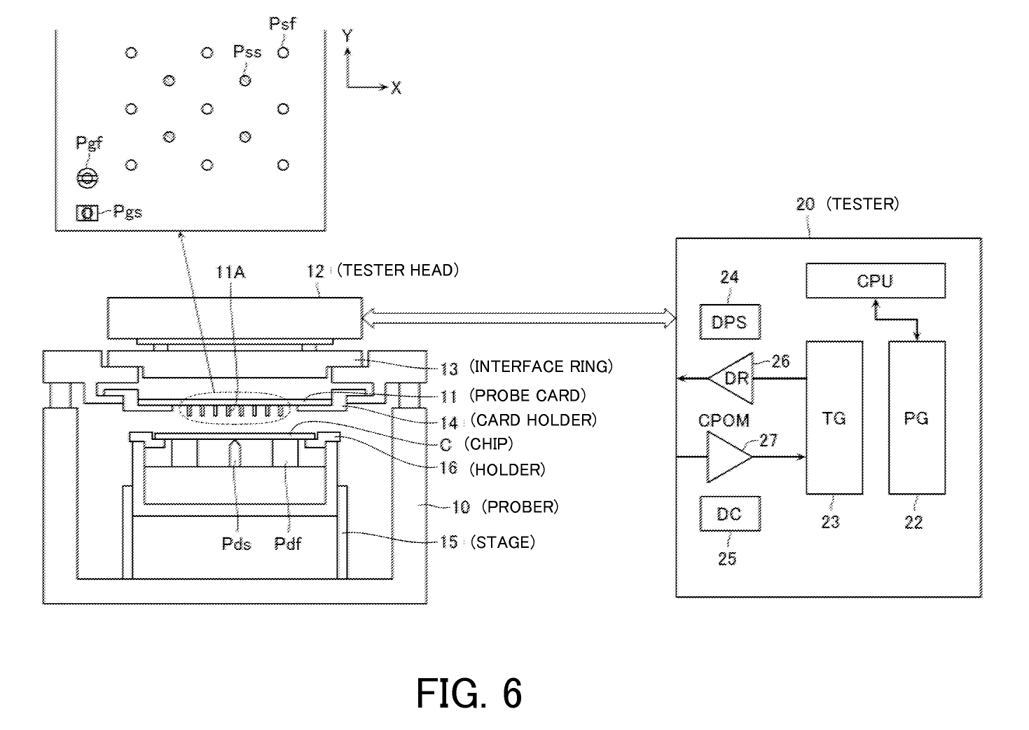

A configuration of the apparatus of measuring the semiconductor device of the embodiment will be described with reference to FIG. 6. The apparatus of measuring the semiconductor device of the embodiment includes a prober 10, a probe card 11 (a second unit), a tester head 12, an interface ring 13, card holder 14, a stage 15 (a first unit) and holder 16.

The tester head 12 is configured to be capable of an electrical connection to the probe card 11 through the interface ring 13. The tester head 12 is electrically connected to a tester 20 (a third unit). Current and voltage which are required in a measurement (test) are supplied to the tester head 12 by the tester 20.

The card holder 14 is a stage on which the probe card 11 is placed. The stage 15 on which the semiconductor chip C or the wafer W is placed is disposed inside a cabinet of the prober 10. The holder 16 to fix the semiconductor chip C or the wafer W is provided on the stage 15. A drain force terminal Pdf and a drain sense terminal Pds for contact with a rear surface of the semiconductor chip C or a rear surface of the wafer W are provided in the stage 15. The voltage and the signal which are required in the measurement (test) are supplied to the drain force terminal Pdf and the drain sense terminal Pds via the tester head 12.

The tester 20 includes a CPU (Central Processing Unit) 21, a pattern generator 22, a timing generator 23, a voltage generation circuit 24, a driver 26, a comparator 27, and the like inside. The CPU 21 is a control circuit to control the whole tester 20, and controls each portion of the tester 20 using a test program loaded into the tester 20 from an outside. The pattern generator 22 generates a test pattern suitable for various types of test in accordance with the test program and a control signal outputted by the CPU 21. The timing generator 23 generates a timing signal in accordance with the test program and the control signal. The timing signal defines timing for transmission of the test pattern, and timing for state determination. The voltage generation circuit 24 is a circuit to generate voltage to be supplied to the semiconductor chip C and the wafer W which are objects to be measured. The driver 26 is a circuit to output the test pattern generated by the pattern generator 22 to the tester head 12. The comparator 27 is a circuit to judge signal which is outputted from the semiconductor chip C or the wafer W in response to input of the test pattern. The pattern generator 22, the voltage generation circuit 24 and the driver 26 serve as a power supply unit outputting voltage to various terminals which are described later.

As shown in an enlarged view of FIG. 6, the probe card 11 includes a source force terminal Psf and a source sense terminal Pss for contact with the source electrode 2. The probe card 11 includes a gate force terminal Pgf and a gate sense terminal Pgs for contact with the gate electrode 1. The voltage and the signal which are required in the measurement (the test) are supplied to the source force terminal Psf, the source sense terminal Pss, the gate force terminal Pgf and the gate sense terminal Pgs through the tester head 12. The drain force terminal Pdf, the drain sense terminal Pds, the source force terminal Psf and the source sense terminal Pss are employed to a well known Kelvin connection. So-called 4-terminal measurement is performed. In an element having a low ON resistance, the 4-terminal measurement enables a measurement accuracy to be highly maintained.

A set of the gate force terminal Pgf and the gate sense terminal Pgs is prepared for the one gate electrode 1. On the other hand, the two or more source force terminals Psf and the two or more source sense terminals Pss are prepared for the one source electrode 2 of the semiconductor chip C.

As an example, the source force terminals Psf are arranged on a plane along an X-direction and a Y-direction shown in FIG. 6 at a substantially equal spacing. The source force terminals Psf are arranged in a matrix pattern, for example. The example shown in FIG. 6 shows the arrangement of an orthogonal grid pattern. An arrangement of a hound's tooth check pattern may be available instead of the arrangement of the orthogonal grid pattern. Various types of arrangement may be available as long as distances between the adjacent source force terminals Psf are approximately equal to each other.

Similarly, the source sense terminals Pss are arranged in the matrix pattern so that a circumference of the source sense terminal Pss is surrounded by the source force terminals Psf. In other word, the two or more source force terminals Psf are disposed in each circumference of the source sense terminal Pss. It is preferable that a first distance and a second distance are approximately equal. The first distance is a distance between the source sense terminal Pss and one of the source force terminals Psf. The second distance is a distance between the source sense terminal Pss and another one of the source force terminals Psf. However, that the first distance and the second distance are approximately equal is not limited. In addition, it is enough that the only one source sense terminal Pss is prepared to the one source electrode 2 unlike the source force terminal Psf. When preparing the one source sense terminal Pss, it is preferable that the two or more source force terminals Psf are disposed so as to enclose the circumference of the one source sense terminal Pss.

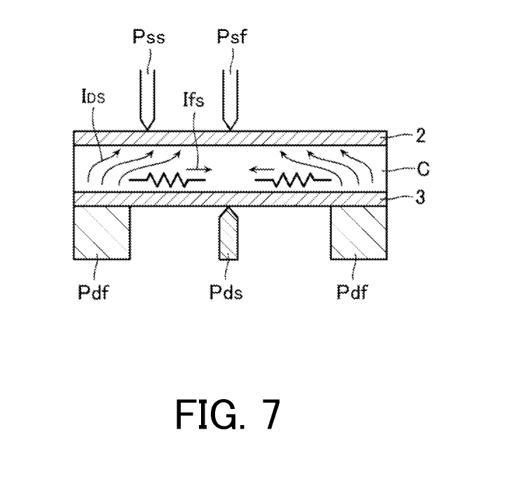

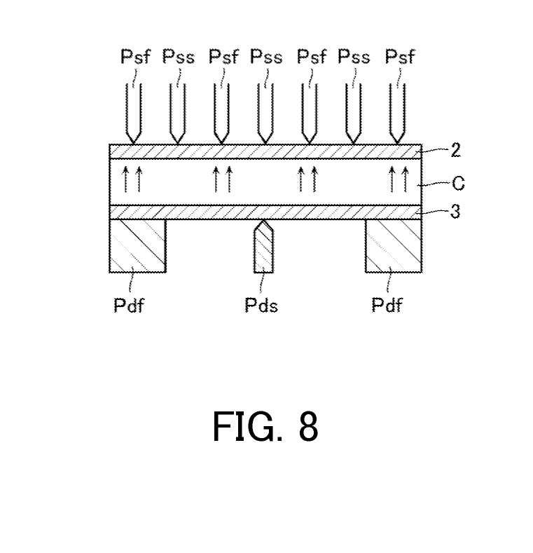

An advantage of the first embodiment will be described with reference to FIGS. 7 and 8. FIG. 7 is a schematic view explaining a comparative example of the first embodiment. In the comparative example, only one set of the source force terminal Psf and the source sense terminal Pss is prepared to the one source electrode 2. Since a current (IDS) pass disproportionately exists in a portion of the semiconductor chip C, a large variation in voltage drop of the semiconductor chip C occurs. Due to the disproportion of the current pass described above, a large voltage drop due to current (Ifs) between the drain force terminal Pdf and the drain sense terminal Pds also occurs. As a result, a suitable measurement of the semiconductor chip C especially having a low ON resistance becomes difficult.

On the other hand, in the first embodiment, the tow or more source force terminals Psf for a connection to the source electrode 2 are arranged at a substantially equal spacing. As shown in FIG. 8, current which flows between the source electrode 2 and the drain electrode 3 flows approximately uniformly in the whole semiconductor chip C without disproportionately flowing in a portion of the semiconductor chip C. The much current has a perpendicular component to the substrate of the semiconductor chip C (the upper surface of the wafer). A variation in voltage drop between the semiconductor chips C is reduced.

The source sense terminal Pss is disposed so that the circumference of the source sense terminal Pss is surrounded by the two or more source force terminals Pfs. Less current between the drain force terminal Pdf and the drain sense terminal Pds flows. Voltage drop between the drain force terminal Pdf and the drain sense terminal Pds is also reduced. Accordingly, a suitable measurement and an inspection of the semiconductor chip are realized.

As described above, the description has been made here as to the case where the semiconductor chip C after dicing has been the measuring object. However, the wafer W before dicing may be a measuring object. A measurement similar to the measurement described above may be performed.

### Second Embodiment

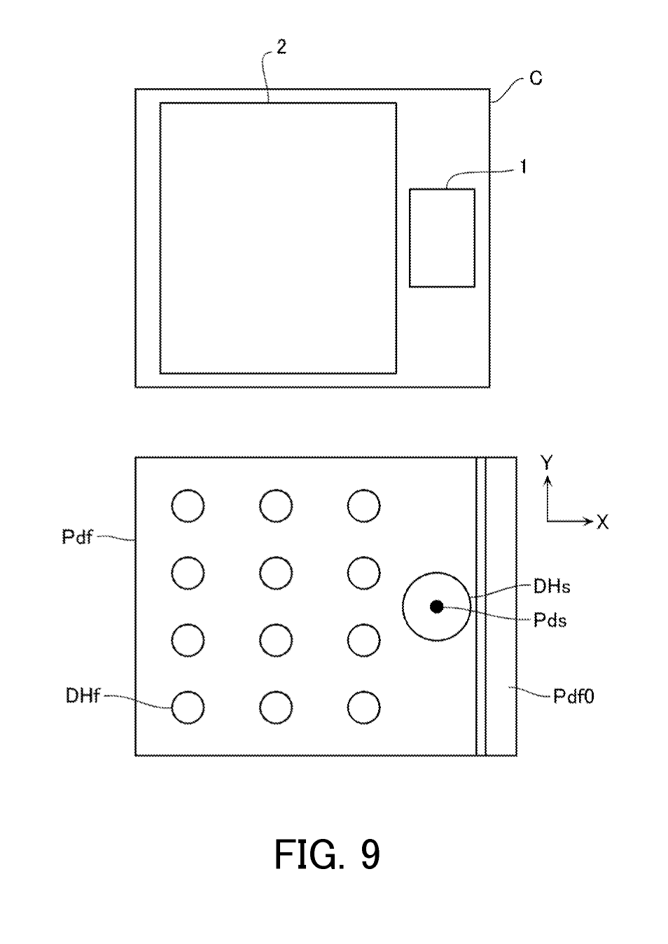

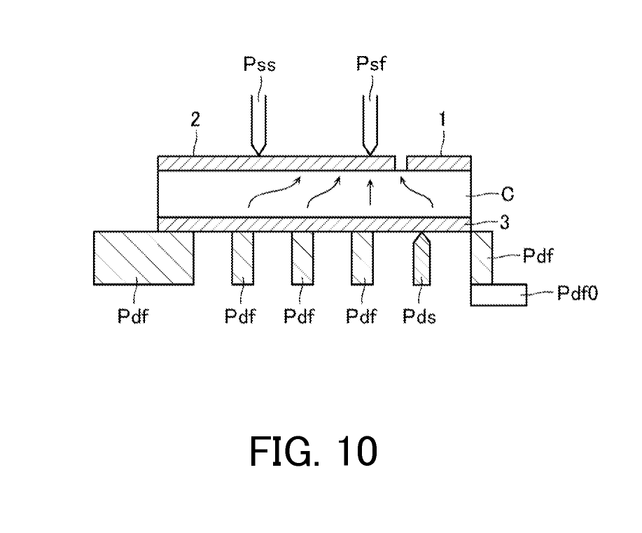

An apparatus of measuring a semiconductor device of a second embodiment will be described with reference to FIGS. 9 and 10. A whole configuration of the apparatus of measuring the semiconductor device is approximately the same as the apparatus of the first embodiment (FIG. 6). A semiconductor chip C and a wafer W may be also the same as the semiconductor chip C and the wafer W of the first embodiment.

The second embodiment differs from the first embodiment in the structures of the drain force terminal Pdf and the drain sense terminal Pds. As shown in FIG. 9, the drain force terminal Pdf of the second embodiment is a plate electrode having a length of an X-direction and a length of a Y-direction so as to be in contact with the drain electrode 3 in plane contact. The plate electrode has two or more first openings DHf passing through the plate electrode and being arranged at an equal spacing in the X-direction and Y-direction. The first openings DHf are provided just below the source electrode 2. Each of the first openings DHf may have a circular shape shown in FIG. 9, or another shape such as a rectangular shape. The first openings DHf are arranged in a grid pattern shown in FIG. 9. However, the first openings DHf may be arranged in a hound's tooth check pattern and the like as long as being arranged at an equal spacing.

A second opening DHs passing through the plate electrode of the drain force terminal PDf is provided in a circumference of the first openings DHf. The drain sense terminal Pds is provided inside the second opening DHs. The Second opening DHs and the drain sense terminal Pds are provided in a position that is separated from the drain electrode 3 and the source electrode 2 at a predetermined distance. The position is near just below the gate electrode 1, for example. A measurement of voltage can be performed without an influence of voltage drop generated due to an influence of the current between the drain and the source.

In addition, the contact electrode PdfO to apply voltage to the drain force terminal Pdf from the outside is connected to an edge of the drain force terminal Pdf.

In the second embodiment, current which flows between the source electrode 2 and the drain electrode 3 flows approximately uniformly in the semiconductor chip C without disproportionately flowing. The much current has a perpendicular component to the semiconductor chip C (the upper surface). A variation in voltage drop between the semiconductor chips C is reduced. Current between the drain force terminal Pdf and the drain sense terminal Pds is also lowered. Voltage drop between the drain force terminal Pdf and the drain sense terminal Pds is also lowered. Accordingly, a suitable measurement and an inspection of the semiconductor chip can be realized.

The drain sense terminal Pss is provided in a position that is separated from the drain electrode 3 and the source electrode 2 at a predetermined distance. The position is near just below the gate electrode 1, for example. A measurement of voltage can be performed without an influence of voltage drop generated due to an influence of the current between the drain and the source.

### Third Embodiment

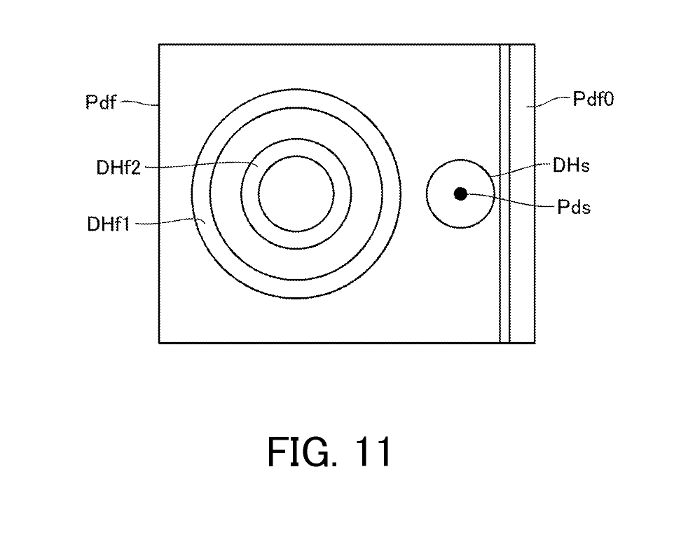

An apparatus of measurement a semiconductor device of a third embodiment will be described with reference to FIG. 11. A whole configuration of the apparatus of measuring the semiconductor device is approximately the same as the apparatus of the first embodiment (FIG. 6). A semiconductor chip C and a wafer W may be also the same as the semiconductor chip C and the wafer W of the first embodiment.

As well as the second embodiment, a drain force terminal Pdf has two or more first openings (two first openings DHf1, DHf2, for example) passing through the plate electrode of the drain force terminal Pdf. As shown in FIG. 11, the first openings DHf1, DHf2 of the embodiment have ring shapes concentric to each other. The configuration of the third embodiment also gives the same advantage as the configuration of the second embodiment.

### Fourth Embodiment

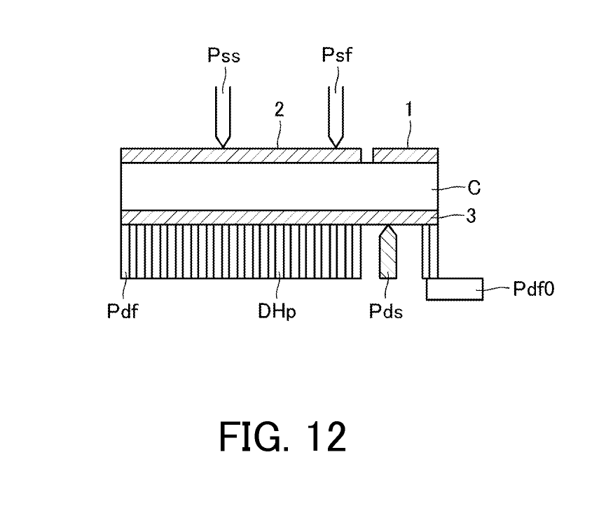

An apparatus of measuring a semiconductor device of a fourth embodiment will be described with reference to FIG. 12. A whole configuration of the apparatus of measuring the semiconductor device is approximately the same as the apparatus of the first embodiment (FIG. 6). A semiconductor chip C and a wafer W may be also the same as the semiconductor chip C and the wafer W of the first embodiment.

A drain force terminal Pdf is made of porous metal containing a lot of holes DHp inside. Various metallic materials such as copper, aluminum and the like are available as the material of the porous metal. Forging procedure and sintering method are known as a method of fabricating the porous metal. The porous metal of the embodiment can be fabricated by any of forging procedure and sintering method. The configuration of the fourth embodiment also gives the same advantage as the configuration of the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An apparatus of measuring a semiconductor device, comprising:
a first sense terminal configured to be electrically connected to a first electrode provided on a first surface of a semiconductor device;
a first force terminal configured to be electrically connected to the first electrode of the semiconductor device;
a second sense terminal configured to be electrically connected to a second electrode provided on a second surface of the semiconductor device, the second surface being opposite to the first surface; and
a plurality of second force terminals disposed in a circumference of the second sense terminal, and configured to be electrically connected to the second electrode of the semiconductor device.

2. The apparatus of measuring the semiconductor device according to claim 1, wherein
a first distance and a second distance are approximately equal, the first distance is a distance between the second sense terminal and one of the second force terminals, the second distance is a distance between the second sense terminal and another one of the second force terminals.

3. The apparatus of measuring the semiconductor device according to claim 1, wherein
in a plane surface parallel to the second surface, the second force terminals are arranged in a grid pattern.

4. The apparatus of measuring the semiconductor device according to claim 3, wherein
the grid pattern is a orthogonal grid pattern or a hound's tooth check pattern.

5. The apparatus of measuring the semiconductor device according to claim 1, further comprising:
a third sense terminal to be connected to a third electrode provided on the second surface; and
a third force terminal to be connected to the third electrode, wherein
the semiconductor device is a vertical transistor.

6. The apparatus of measuring the semiconductor device according to claim 1, further comprising:
a first unit configured to hold the semiconductor device, and connect the first force terminal and the first sense terminal to the first electrode of the semiconductor device;
a second unit configured to connect the second sense terminal and the second force terminal to the second electrode of the semiconductor device; and
a third unit configured to supply a predetermined current between the first force terminal and the second force terminal, and make measurement of voltage drop between the first sense terminal and the second sense terminal.

7. An apparatus of measuring a semiconductor device, comprising:
a first sense terminal configured to be electrically connected to a first electrode provided on a first surface of a semiconductor device;
a first force terminal including a plate electrode having a plurality of first openings, the plate electrode configured to be electrically connected to the first electrode of the semiconductor device in plane contact;
a second sense terminal configured to be electrically connected to a second electrode provided on a second surface of the semiconductor device, the second surface being opposite to the first surface; and
a second force terminal configured to be electrically connected to the second electrode of the semiconductor device.

8. The apparatus of measuring the semiconductor device according to claim 7, wherein
the first openings are disposed at an approximately equal spacing.

9. The apparatus of measuring the semiconductor device according to claim 8, wherein
the first openings are arranged in a orthogonal grid pattern or a hound's tooth check pattern.

10. The apparatus of measuring the semiconductor device according to claim 7, wherein
the first openings are ring shaped openings concentric to each other.

11. The apparatus of measuring the semiconductor device according to claim 7, wherein
the plate electrode has a second opening passing through the plate electrode, in a circumference of the first openings, the first sense terminal is provided inside the second opening.

12. The apparatus of measuring the semiconductor device according to claim 7, wherein
the first force terminal contains porous metal.

13. The apparatus of measuring the semiconductor device according to claim 12, wherein
the material of the porous metal is copper or aluminum.

14. The apparatus of measuring the semiconductor device according to claim 7, further comprising:
a third sense terminal to be connected to a third electrode provided on the second surface; and
a third force terminal to be connected to the third electrode, wherein
the semiconductor device is a vertical transistor.

15. The apparatus of measuring the semiconductor device according to claim 14, wherein
the second opening is provided in a portion of the plate electrode opposite to the third electrode, the first sense terminal is to be connected to a portion of the first electrode opposite to the third electrode.

16. The apparatus of measuring the semiconductor device according to claim 7, further comprising:
a first unit configured to hold the semiconductor device, and connect the first sense terminal and the first force terminal to the first electrode of the semiconductor device;
a second unit configured to connect the second sense terminal and the second force terminal to the second electrode of the semiconductor device; and
a third unit configured to supply a predetermined current between the first force terminal and the second force terminal, and make measurement of voltage drop between the first sense terminal and the second sense terminal.
